(19) United States
(12) Patent Application Publication
(10) Pub. No.: US 2025/0024638 A1
(43) Pub. Date: Jan. 16, 2025

(54) TWO-PHASE IMMERSION COOLING SYSTEM

(71) Applicant: Vertiv Corporation, Columbus, OH (US)

(72) Inventors: Russell Tipton, Westerville, OH (US); Craig Shores, Arlington, OH (US)

(21) Appl. No.: 18/351,341

(22) Filed: Jul. 12, 2023

(51) Int. Cl. H05K 7/20

(52) U.S. Cl. CPC H05K 7/203; H05K 7/20318; H05K 7/20672; H05K 7/207

(57) ABSTRACT

A two-phase immersion cooling system can include a pressure vessel with one or more processors, a two-phase refrigerant, and one or more condenser tubes within the vessel. The refrigerant can flow past the processor(s) by thermosyphon. The refrigerant can be configured to extract heat from the processor(s). In at least one embodiment, a liquid phase of the refrigerant can fully, or at least partially, cover the processor(s). The condenser tube(s) can be configured to receive cooling fluid into and transmit cooling fluid out of the vessel, thereby removing heat from the vessel.

### CROSS REFERENCE TO RELATED APPLICATIONS

This application claims the benefit of U.S. Provisional Patent Application No. 63/388,638, filed Jul. 12, 2022, the entire contents of which are incorporated herein by reference.

### STATEMENT REGARDING FEDERALLY SPONSORED RESEARCH OR DEVELOPMENT

Not applicable.

### REFERENCE TO APPENDIX

Not applicable.

### BACKGROUND OF THE INVENTION

Field of the Invention. The present disclosure relates generally to cooling systems for information technology systems and more specifically relates to two-phase immersion cooling for information technology systems.

Description of the Related Art Artificial intelligence (AI), data analytics (DA), and machine learning advancements are pushing the need for speed, which is resulting in central processing unit (CPU), graphics processing unit (GPU), and data processing unit (DPU) power densities beyond 5 Watts per square centimeter (W/cm²). Power densities for these and other applications are forecast to become 100 W/cm² and higher. This power density combined with a drive for sustainability makes air-cooling of dense Information Technology (IT) heat sources less practical. Liquids can have much better thermal transport properties than gasses, such as air.

However, current liquid cooling techniques are lacking in some respects. For example, current techniques include operation at or around atmospheric pressures and/or the use of relatively high boiling point dielectric fluids as refrigerants. While such techniques may provide easy access to their processors in some circumstances, they also can be inefficient, require expensive fluids, present environmental hazards, or various combinations thereof.

### BRIEF SUMMARY OF THE INVENTION

Applicants have created new and useful devices, systems and methods for two-phase immersion cooling for information technology systems.

In at least one embodiment, a two-phase immersion cooling system can include a pressure vessel, with one or more processors therein, a two-phase refrigerant, and one or more condenser tubes within the vessel. The refrigerant can flow past the processor(s) by thermosyphon. The refrigerant can be configured to extract heat from the processor(s). In at least one embodiment, a liquid phase of the refrigerant can fully, or at least partially, cover the processor(s). The condenser tube(s) can be configured to receive cooling fluid into and transmit cooling fluid out of the vessel, thereby removing heat from the vessel.

In at least one embodiment, the vessel can be, or include, a chamber, which can include a flange and a plate bolted to the flange. The processor(s) can be mounted to, or otherwise physically secured to, the plate. In at least one embodiment, the processor(s) can receive power and communications through the plate. The vessel can include one or more valves configured to supply and/or drain the refrigerant to/from the vessel. In at least one embodiment, these valves can include, for example, Schrader valves or the like.

In at least one embodiment, the processor(s) can include a coating on an exterior surface thereof. Such a coating can minimize a temperature difference between the refrigerant and the processor(s) and/or the exterior surface thereof. Such a coating can electrically insulate the processor(s) from the refrigerant. In at least one embodiment, the processor(s) and/or the exterior surface thereof can be configured to electrically insulate the one or more processors from the refrigerant.

In at least one embodiment, the liquid phase of the refrigerant completely covers the processor(s). In at least one embodiment, one or more of the condenser tube(s) are positioned above the liquid phase of the refrigerant, such that the condenser tube(s) can condense a gaseous phase of the refrigerant. In at least one embodiment, all of the condenser tube(s) are positioned above the liquid phase of the refrigerant. In at least one embodiment, the refrigerant comprises a dielectric.

In at least one embodiment, the system can include a controller to control a flow rate of the cooling fluid through the condenser tube(s) based at least in part on a temperature of the refrigerant. In at least one embodiment, the system can include a controller to control the flow rate of the cooling fluid through the condenser tube(s) based at least in part on a power consumption of the processor(s). In at least one embodiment, the system can include a controller to control the flow rate of the cooling fluid through the condenser tube(s) based at least in part on a temperature of the processor(s). In at least one embodiment, the system can include a controller to control the flow rate of the cooling fluid through the condenser tube(s) based on a combination of any of a temperature of the refrigerant, a power consumption of the processor(s), and a temperature of the processor(s).

In at least one embodiment, a two-phase immersion cooling system can include a first pressure vessel; a second pressure vessel in selective fluid communication with the first pressure vessel; one or more processors within the second pressure vessel; a two-phase refrigerant within the first and second pressure vessels; and one or more condenser tubes within the first pressure vessel. In at least one embodiment, the refrigerant can be configured to extract heat from the processor(s). The refrigerant can flow past the processor(s) by thermosyphon. In at least one embodiment, a liquid phase of the refrigerant can fully, or at least partially, cover the processor(s). In at least one embodiment, the condenser tube(s) can be configured to receive cooling fluid into and transmit cooling fluid out of the first pressure vessel, thereby removing heat from the second pressure vessel.

In at least one embodiment, the system can be modular. For example, in at least one embodiment, the system can include a third pressure vessel in selective fluid communication with the first pressure vessel, and one or more processors within the third pressure vessel, wherein the condenser tube(s) are further configured to remove heat from the third pressure vessel. In at least one embodiment, the third pressure vessel is identical to the second pressure vessel. In at least one embodiment, the third pressure vessel is functionally independent from the second pressure vessel, such that, for example, one can be cooled while the other is not, one can be cooled at a different rate than the other, one can be drained and opened while the other is being cooled, or any combination thereof.

In at least one embodiment, the system can include one or more lines connected between the first pressure vessel and the second pressure vessel. In at least one embodiment, the system can include a first and a second line connected between the first pressure vessel and the second pressure vessel. For example, in at least one embodiment, the system can include a liquid line connected between a lower portion of the first pressure vessel and a lower portion of the second pressure vessel and a vapor line connected between an upper portion of the first pressure vessel and an upper portion of the second pressure vessel. In at least one embodiment, the system can include one or more valves in either, or both, of the line(s) to selectively isolate the second pressure vessel from the first pressure vessel. For example, in at least one embodiment, the system can include one or more valves in the liquid line and one or more valves in the vapor line to selectively isolate the second pressure vessel from the first pressure vessel. In at least one embodiment, these valves can include, for example, quarter turn ball valves, or the like. In at least one embodiment, at least one of the valves is configured to control flow of the refrigerant between the second pressure vessel and the first pressure vessel.

In at least one embodiment, the second pressure vessel can be, or include, a chamber, which can include a flange and a plate bolted to the flange. The processor(s) can be mounted to, or otherwise physically secured to, the plate. In at least one embodiment, the processor(s) can receive power and communications through the plate. In at least one embodiment, the second pressure vessel can include one or more valves configured to supply and/or drain the refrigerant to/from the second pressure vessel. In at least one embodiment, these valves can include, for example, Schrader valves or the like.

In at least one embodiment, the processor(s) can include a coating on an exterior surface thereof. Such a coating can minimize a temperature difference between the refrigerant and the processor(s) and/or the exterior surface thereof. Such a coating can electrically insulate the processor(s) from the refrigerant. In at least one embodiment, the processor(s) and/or the exterior surface thereof can be configured to electrically insulate the one or more processors from the refrigerant.

In at least one embodiment, the liquid phase of the refrigerant completely covers the processor(s). In at least one embodiment, one or more of the condenser tube(s) are positioned above the liquid phase of the refrigerant, such that the condenser tube(s) can condense a gaseous phase of the refrigerant. In at least one embodiment, all of the condenser tube(s) are positioned above the liquid phase of the refrigerant. In at least one embodiment, the refrigerant comprises a dielectric.

In at least one embodiment, the system can include a controller to control a flow rate of the cooling fluid through the condenser tube(s) based at least in part on a temperature of the refrigerant. In at least one embodiment, the system can include a controller to control the flow rate of the cooling fluid through the condenser tube(s) based at least in part on a power consumption of the processor(s). In at least one embodiment, the system can include a controller to control the flow rate of the cooling fluid through the condenser tube(s) based at least in part on a temperature of the processor(s). In at least one embodiment, the system can include a controller to control the flow rate of the cooling fluid through the condenser tube(s) based on a combination of any of a temperature of the refrigerant, a power consumption of the processor(s), and a temperature of the processor(s).

In at least one embodiment, the system can include a controller to control a flow rate of the refrigerant based at least in part on a temperature of the refrigerant. In at least one embodiment, the system can include a controller to control the flow rate of the refrigerant based at least in part on a power consumption of the processor(s). In at least one embodiment, the system can include a controller to control the flow rate of the refrigerant based at least in part on a temperature of the processor(s). In at least one embodiment, the system can include a controller to control the flow rate of the refrigerant based on a combination of any of a temperature of the refrigerant, a power consumption of the processor(s), and a temperature of the processor(s). Such a controller can control the flow rate of the refrigerant past the processor(s) and/or between the first pressure vessel and the second pressure vessel.

### BRIEF DESCRIPTION OF THE SEVERAL VIEWS OF THE DRAWINGS

FIG. 1 is a top view schematic diagram of one of many embodiments of a two-phase immersion cooling system according to the disclosure.

FIG. 2 is a side view schematic diagram of one of many embodiments of a two-phase immersion cooling system according to the disclosure.

FIG. 3 is a schematic diagram of one of many embodiments of a two-phase immersion cooling system according to the disclosure.

### DETAILED DESCRIPTION OF THE INVENTION

The Figures described above and the written description of specific structures and functions below are not presented to limit the scope of what Applicants have invented or the scope of the appended claims. Rather, the Figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms.

The use of a singular term, such as, but not limited to, “a,” is not intended as limiting of the number of items. Also, the use of relational terms, such as, but not limited to, “top,” “bottom,” “left,” “right,” “upper,” “lower,” “down,” “up,” “side,” and the like are used in the written description for clarity in specific reference to the Figures and are not intended to limit the scope of the inventions or the appended claims. The terms “including” and “such as” are illustrative and not limitative. The terms “couple,” “coupled,” “coupling,” “coupler,” and like terms are used broadly herein and can include any method or device for securing, binding, bonding, fastening, attaching, joining, inserting therein, forming thereon or therein, communicating, or otherwise associating, for example, mechanically, magnetically, electrically, chemically, operably, directly or indirectly with intermediate elements, one or more pieces of members together and can further include without limitation integrally forming one functional member with another in a unity fashion. The coupling can occur in any direction, including rotationally. Further, all parts and components of the disclosure that are capable of being physically embodied inherently include imaginary and real characteristics regardless of whether such characteristics are expressly described herein, including but not limited to characteristics such as axes, ends, inner and outer surfaces, interior spaces, tops, bottoms, sides, boundaries, dimensions (e.g., height, length, width, thickness), mass, weight, volume and density, among others.

Applicants have created new and useful devices, systems and methods for two-phase immersion cooling for information technology systems. In at least one embodiment, a cooling system according to the disclosure can include one or more processors disposed within a pressure vessel, a two-phase refrigerant, and one or more condenser tubes disposed at least partially within the vessel. Refrigerant can be configured to flow via thermosyphoning for extracting heat from the processor(s). In at least one embodiment, a liquid phase refrigerant can at least partially cover the processor(s). The condenser tube(s) can be configured to route cooling fluid into and out of the vessel for removing heat from the vessel.

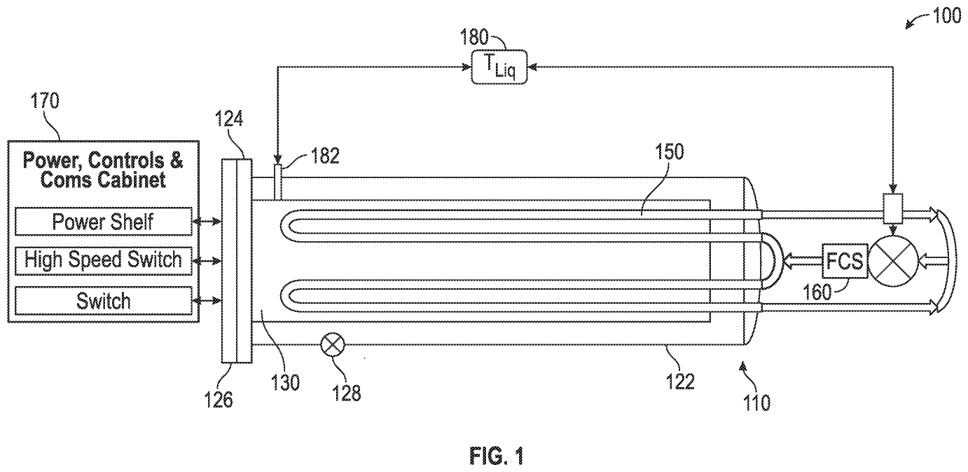

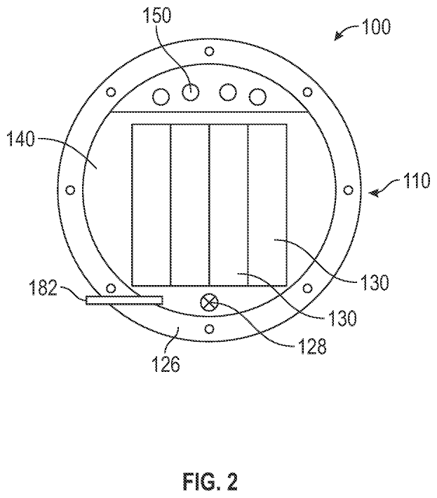

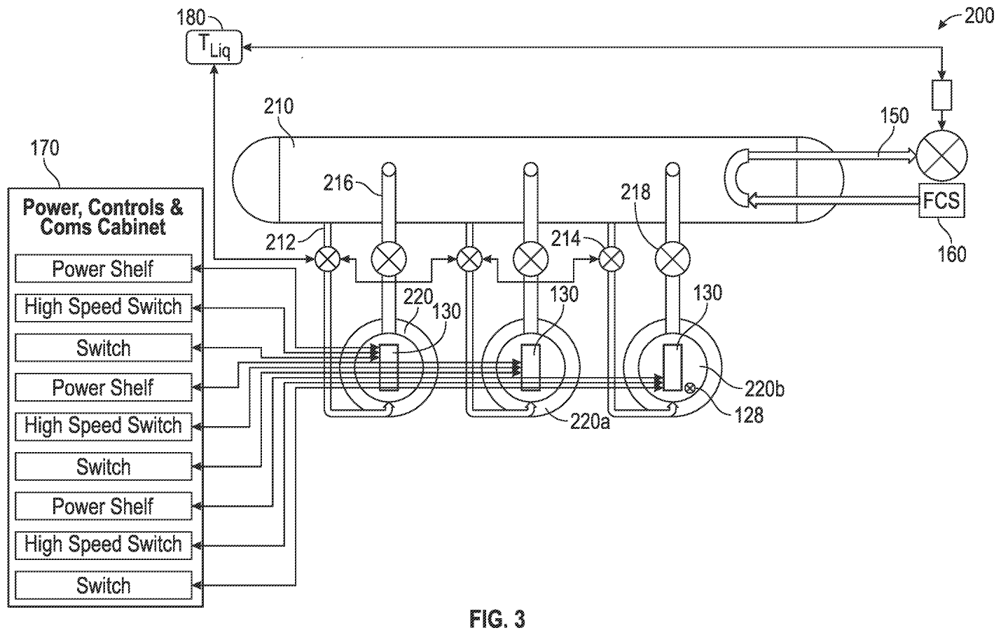

FIG. 1 is a top view schematic diagram of one of many embodiments of a two-phase immersion cooling system according to the disclosure. FIG. 2 is a side view schematic diagram of one of many embodiments of a two-phase immersion cooling system according to the disclosure. FIG. 3 is a schematic diagram of one of many embodiments of a two-phase immersion cooling system according to the disclosure. FIGS. 1-3 are described in conjunction with one another.

In at least one embodiment, a two-phase immersion cooling system 100 according to the disclosure can include one or more pressure vessels 110, with one or more processors 130 therein, one or more two-phase refrigerants 140, one or more condenser tubes 150 within the vessels 110, or any combination thereof. Refrigerant 140 can flow past the processor(s) 130 by thermosyphon, with or without the assistance of a pump. The refrigerant 140 can be configured to extract heat from the processor(s) 130. In at least one embodiment, a liquid phase of the refrigerant 140 can fully, or at least partially, cover the processor(s) 130. The condenser tube(s) 150 can be configured to receive cooling fluid into and transmit cooling fluid out of the vessel 110, thereby removing heat from the vessel 110. The cooling fluid, such as chilled water or a propylene glycol mixture, can be supplied by a facility cooling system (FCS) 160, which may be external to, or integrated within, the system 100. In at least one embodiment, the condenser tube(s) 150 can be part of a shell and tube heat exchanger, e.g., as illustrated in FIGS. 1-3 for exemplary purposes. However, this need not be the case, and other configurations are possible, as may be desired or required for a particular implementation of the disclosure. For instance, in at least one embodiment, condenser tube(s) 150 can be or include one or more fluid paths through or within a brazed plate heat exchanger (or portion thereof, as the case may be).

In at least one embodiment, the vessel 110 can be or include one or more chambers 122, which can include one or more flanges 124 and one or more plates 126 bolted to the flange 124. The processor(s) 130 can be mounted to, or otherwise physically secured to, the plate 126. In at least one embodiment, the processor(s) 130 can receive power and communications through the plate 126. For example, the processor(s) 130 can receive power and communications through cabling that connects through, or sealingly penetrates, the plate 126 and thereby electrically couples the processor(s) 130 to one or more power sources, one or more communications sources, one or more data sources, or any combination thereof, any or all of which may be housed in one or more cabinets 170 external to the vessel 110.

The vessel 110 can include one or more valves 128 configured to supply and/or drain the refrigerant 140 to/from the vessel 110, such as for charge, evacuation and/or recovery of refrigerant 140. In at least one embodiment, these valves 128 can be or include, for example, one or more Schrader valves or another type of valve suitable for an implementation of the disclosure.

In at least one embodiment, the processor(s) 130 can include one or more coatings on an exterior surface thereof. Such a coating can minimize a temperature difference between the refrigerant 140 and the processor(s) 130 and/or the exterior surface thereof. Such a coating can electrically insulate the processor(s) 130 from the refrigerant 140. In at least one embodiment, the processor(s) 130 and/or the exterior surface thereof can be configured to electrically insulate processor(s) 130 from the refrigerant 140.

In at least one embodiment, the liquid phase of the refrigerant 140 completely covers the processor(s) 130. In at least one embodiment, one or more of the condenser tube(s) 150 are positioned above the liquid phase of the refrigerant 140, such that the condenser tube(s) 150 can condense a gaseous phase of the refrigerant 140. In at least one embodiment, all of the condenser tube(s) 150 are positioned above the liquid phase of the refrigerant 140. In at least one embodiment, the refrigerant 140 comprises a dielectric.

In at least one embodiment, the system 100 can include one or more controllers 180 to control a flow rate of the cooling fluid through the condenser tube(s) 150 based at least in part on a temperature of the refrigerant 140. In at least one embodiment, the system 100 can include one or more temperature sensors 182 to sense the temperature of the refrigerant 140. In at least one embodiment, the system 100 can include one or more controllers 180 to control the flow rate of the cooling fluid through the condenser tube(s) 150 based at least in part on a power consumption of the processor(s) 130. In at least one embodiment, the system 100 can include one or more controllers 180 to control the flow rate of the cooling fluid through the condenser tube(s) 150 based at least in part on a temperature of the processor(s) 130. In at least one embodiment, the system 100 can include one or more temperature sensors 182 to sense the temperature of the processor(s) 130. In at least one embodiment, the system 100 can include one or more controllers 180 to control the flow rate of the cooling fluid through the condenser tube(s) 150 based on a combination of any of a temperature of the refrigerant 140, a power consumption of the processor(s) 130, and a temperature of the processor(s) 130.

In at least one embodiment, a two-phase immersion cooling system 200 according to the disclosure can include one or more first pressure vessels 210, one or more second pressure vessels 220 in selective fluid communication with the first pressure vessel 210, one or more processors 130 within the second pressure vessel 220, one or more two-phase refrigerants 140 within the first and second pressure vessels 210, 220, one or more condenser tubes 150 within the first pressure vessel 210, or any combination thereof. In at least one embodiment, the refrigerant 140 can be configured to extract heat from the processor(s) 130. The refrigerant 140 can flow past the processor(s) 130 by thermosyphon. In at least one embodiment, a liquid phase of the refrigerant 140 can fully, or at least partially, cover the processor(s) 130. In at least one embodiment, the condenser tube(s) 150 can be configured to receive cooling fluid into and transmit cooling fluid out of the first pressure vessel 210, thereby removing heat from the second pressure vessel 220. The cooling fluid, such as chilled water or a propylene glycol mixture can be supplied by an FCS 160, which may be external to, or integrated within, the system 200.

In at least one embodiment, the system 200 can be modular. For example, in at least one embodiment, the system 200 can include one or more third pressure vessels 220a in selective fluid communication with the first pressure vessel 210, and one or more processors 130 within the third pressure vessel 220a. In at least one embodiment, the condenser tube(s) 150 can remove heat from the third pressure vessel 220a. In at least one embodiment, the third pressure vessel 220a can be identical to the second pressure vessel 220. In at least one embodiment, the third pressure vessel 220a can be functionally independent from the second pressure vessel 220, such that, for example, one can be cooled while the other is not, one can be cooled at a different rate than the other, one can be drained and opened while the other is being cooled, or any combination thereof.

In at least one embodiment, the system 200 can include more than two processor housing pressure vessels 220. For example, the first pressure vessel 210 can be referred to as a primary pressure vessel 210 and the second pressure vessel 220 can be referred to as a secondary pressure vessel 220, 220a, 220b. In at least one embodiment, the system 200 can include multiple secondary pressure vessels 220, 220a, 220b, each housing processors 130, in selective fluid communication with the first pressure vessel 210. In at least one embodiment, condenser tube(s) 150 can remove heat from any or all of the multiple secondary pressure vessels 220, 220a, 220b. The secondary pressure vessels 220, 220a, 220b can all be identical to the second pressure vessel 220, as described herein, or there can be differences between the secondary pressure vessels 220, 220a, 220b. In at least one embodiment, the secondary pressure vessels 220, 220a, 220b can be functionally independent from each other, such that, for example, one or more secondary pressure vessels 220, 220a, 220b can be cooled while one or more are not, one or more secondary pressure vessels 220, 220a, 220b can be cooled at a different rate than others, one or more secondary pressure vessels 220, 220a, 220b can be drained and opened while others are being cooled, or any combination thereof.

In at least one embodiment, the system 200 can include one or more lines 212, 216 connected between the first pressure vessel 210 and the second pressure vessel 220. In at least one embodiment, the system 200 can include a first and a second line 212, 216 connected between the first pressure vessel 210 and the second pressure vessel 220. For example, in at least one embodiment, the system 200 can include one or more liquid lines 212 connected between a lower portion of the first pressure vessel 210 and a lower portion of the second pressure vessel 220 and one or more vapor lines 216 connected between an upper portion of the first pressure vessel 210 and an upper portion of the second pressure vessel 220. In at least one embodiment, the system 200 can include one or more valves 214, 218 in any or all of the line(s) 212, 216 to selectively isolate the second pressure vessel 220 from the first pressure vessel 210. For example, in at least one embodiment, the system 200 can include one or more valves 214 in the liquid line 212 and one or more valves 218 in the vapor line 216 to selectively isolate the second pressure vessel 220 from the first pressure vessel 210. In at least one embodiment, valves 214, 218 can be or include, for example, quarter turn (or other) ball valves, gate valves, or other valves suitable for an implementation of the disclosure. In at least one embodiment, at least one of the valves 214, 218 is configured to control flow of the refrigerant 140 between the second pressure vessel 220 and the first pressure vessel 210. In at least one embodiment, at least one of the valves 214, 218 is configured to supply and/or drain the refrigerant to/from the second pressure vessel 220 and/or the first pressure vessel 210.

In at least one embodiment, the second pressure vessel 220 can be similar to the pressure vessel 110 described above. For example, the second pressure vessel 220 can be or include one or more chambers 122, which can include one or more flanges 124 and one or more plates 126 bolted to the flange 124. The processor(s) 130 can be mounted to, or otherwise physically secured to, the plate 126. In at least one embodiment, the processor(s) 130 can receive power and communications through the plate 130, in much the same manner as described above in connection with the pressure vessel 110. In at least one embodiment, the second pressure vessel 220 can include one or more valves 128 configured to supply and/or drain the refrigerant to/from the second pressure vessel 220, such as for charge, evacuation and/or recovery of refrigerant 140. In at least one embodiment, these valves 128 can be or include, for example, one or more Schrader valves or another type of valve suitable for an implementation of the disclosure.

In at least one embodiment, the processor(s) 130 can include one or more coatings on an exterior surface thereof. Such a coating can minimize a temperature difference between the refrigerant 140 and the processor(s) 130 and/or the exterior surface thereof. Such a coating can electrically insulate the processor(s) 130 from the refrigerant 140. In at least one embodiment, the processor(s) 130 and/or the exterior surface thereof can be configured to electrically insulate the processor(s) 130 from the refrigerant 140.

In at least one embodiment, the liquid phase of the refrigerant 140 completely covers the processor(s) 130. In at least one embodiment, one or more of the condenser tube(s) 150 are positioned above the liquid phase of the refrigerant 140, in the first pressure vessel 210, such that the condenser tube(s) 150 can condense a gaseous phase of the refrigerant 140. In at least one embodiment, all of the condenser tube(s) 150 are positioned above the liquid phase of the refrigerant 140. In at least one embodiment, the refrigerant 140 comprises a dielectric.

In at least one embodiment, the system 200 can include one or more controllers 180 to control a flow rate of the cooling fluid through the condenser tube(s) 150 based at least in part on a temperature of the refrigerant 140. In at least one embodiment, the system 200 can include one or more temperature sensors 182 to sense the temperature of the refrigerant 140. In at least one embodiment, the system 200 can include one or more controllers 180 to control the flow rate of the cooling fluid through the condenser tube(s) 150 based at least in part on a power consumption of the processor(s) 130. In at least one embodiment, the system 200 can include one or more controllers 180 to control the flow rate of the cooling fluid through the condenser tube(s) 150 based at least in part on a temperature of the processor(s) 130. In at least one embodiment, the system 200 can include one or more temperature sensors 182 to sense the temperature of processor(s) 130. In at least one embodiment, the system 200 can include one or more controllers 180 to control the flow rate of the cooling fluid through the condenser tube(s) 150 based on a combination of any of a temperature of the refrigerant 140, a power consumption of the processor(s) 130, and a temperature of the processor(s) 130.

In at least one embodiment, the system 200 can include one or more controllers 180 to control a flow rate of the refrigerant 140 between the first pressure vessel 210 and the second pressure vessel 220 based at least in part on a temperature of the refrigerant 140. In at least one embodiment, the system 200 can include one or more temperature sensors 182 to sense the temperature of the refrigerant 140. In at least one embodiment, the system 200 can include one or more controllers 180 to control the flow rate of the refrigerant 140 between the first pressure vessel 210 and the second pressure vessel 220 based at least in part on a power consumption of the processor(s) 130. In at least one embodiment, the system 200 can include one or more controllers 180 to control the flow rate of the refrigerant 140 between the first pressure vessel 210 and the second pressure vessel 220 based at least in part on a temperature of the processor(s) 130. In at least one embodiment, the system 200 can include one or more temperature sensors 182 to sense the temperature of the processor(s) 130. In at least one embodiment, the system 200 can include one or more controllers 180 to control the flow rate of the refrigerant 140 between the first pressure vessel 210 and the second pressure vessel 220 based on a combination of any of a temperature of the refrigerant 140, a power consumption of the processor(s) 130, and a temperature of the processor(s) 130.

The processor(s) 130 described herein can include any combination of central processing units (CPU), graphics processing units (GPU), and data processing units (DPU). The processor(s) 130 and refrigerant 140 described herein can be chosen and/or designed for compatibility with one another. For example, the processor(s) 130 can be designed, configured, and/or modified specifically to be compatible with the refrigerant 140. The refrigerant 140 can have the following properties: ODP=0, GWP<750, ASHRAE A1 (no toxicity, no flammability), low to medium pressure, established transport properties as developed for refrigeration industry, material compatibility with server components, or any combination thereof. Exemplary refrigerants include, but are not limited to, R515B, R513a, R471a, R1233zd(E), or any combination thereof. Material compatibility of the refrigerant 140 combined with purpose-built processor 130 material selection can eliminate the need for activated carbon adsorption filtration.

Throttling the FCS 160 control valve can achieve temperature control of the liquid refrigerant and, thus, optimum temperature of the processor(s) 130. The liquid refrigerant 140 temperature can be measured by an immersion probe. The effectiveness of the thermosyphon can be determined by monitoring the power consumption and temperature of the processor(s) 130.

One embodiment is shown with the processor(s) 130 and the condenser tube(s) 150 in the same pressure vessel 110. A similar embodiment is also shown where the processor(s) 130 are housed in one pressure vessel and the condenser tube(s) 150 are housed in another pressure vessel, which can provide scalability and modularity. In this second embodiment, multiple processor containers, or secondary vessels 220, may be connected to a single primary vessel 210. In this second embodiment, multiple processor containers, or secondary vessels 220, may be connected to multiple primary vessels 210. Boiled vapor phase refrigerant 140 rises to near the top of the primary vessel 210. As the vapor is condensed, the liquid phase refrigerant 140 falls to the bottom and through the liquid line to the bottom of the secondary vessel 220 completing the thermosyphon cycle. Full flow isolation valves in liquid and vapor lines can be installed between the primary vessel 210 and each secondary vessel 220.

Again, throttling the FCS 160 control valve can achieve temperature control of the return liquid phase refrigerant 140. Each module liquid phase refrigerant 140 temperature can be measured individually. One simple form of control can use a highest liquid phase refrigerant 140 temperature against a set point to throttle the FCS 160 control valve. A more intelligent control can determine effectiveness of the thermosyphon for each secondary vessel 220, such as by monitoring the power consumption and/or temperature of each processor 130 in each secondary vessel 220.

Standard and proven refrigeration practices for refrigerant 140 charging and recovery can be followed. For example, after the system 100/200 is assembled, a leak check can be performed, then the system 100/200 can be evacuated to <300 micron, and charged to a predetermined level. When individual access to a secondary vessel 220 is required or desired, one may isolate that secondary vessel 220, recover the charge, perform the service, then repeat the steps for charging. Recovered refrigerant 140 can be reused. Access to a secondary vessel 220 can be accomplished while primary pressure vessel 210 and/or one or more other secondary vessel 220 remain in active use. These procedures, applied correctly, can produce a de minimis loss of charge and support compliance with environmental, health, and safety standards.

In at least one embodiment, a two-phase immersion cooling system can include a pressure vessel, with one or more processors therein, a two-phase refrigerant, and one or more condenser tubes within the vessel. The refrigerant can flow past the processor(s) by thermosyphon, with or without the assistance of a pump. The refrigerant can be configured to extract heat from the processor(s). In at least one embodiment, a liquid phase of the refrigerant can fully, or at least partially, cover the processor(s). The condenser tube(s) can be configured to receive cooling fluid into and transmit cooling fluid out of the vessel, thereby removing heat from the vessel. The cooling fluid, such as chilled water or a propylene glycol mixture, can be supplied by an FCS, which may be external to, or integrated within, the system, in whole or in part.

In at least one embodiment, the vessel can be or include a chamber, which can include a flange and a plate bolted to the flange. The processor(s) can be mounted to, or otherwise physically secured to, the plate. In at least one embodiment, the processor(s) can receive power and communications through the plate. For example, the processor(s) can receive power and communications through cabling that connects through, or sealingly penetrates, the plate and thereby electrically couples the processor(s) to a power source, a communications source, a data source, or any combination thereof, any or all of which may be housed in a cabinet external to the vessel 110. The vessel can include one or more valves configured to supply and/or drain the refrigerant to/from the vessel, which can be or include any type of valve suitable for an implementation of the disclosure.

In at least one embodiment, the processor(s) can include a coating on an exterior surface thereof. Such a coating can minimize a temperature difference between the refrigerant and the processor(s) and/or the exterior surface thereof. Such a coating can electrically insulate the processor(s) from the refrigerant. In at least one embodiment, the processor(s) and/or the exterior surface thereof can be configured to electrically insulate the one or more processors from the refrigerant.

In at least one embodiment, the liquid phase of the refrigerant completely covers the processor(s). In at least one embodiment, one or more of the condenser tube(s) are positioned above the liquid phase of the refrigerant, such that the condenser tube(s) can condense a gaseous phase of the refrigerant. In at least one embodiment, all of the condenser tube(s) are positioned above the liquid phase of the refrigerant. In at least one embodiment, the refrigerant comprises a dielectric.

In at least one embodiment, the system can include a controller to control a flow rate of the cooling fluid through the condenser tube(s) based at least in part on a temperature of the refrigerant. In at least one embodiment, the system can include a controller to control the flow rate of the cooling fluid through the condenser tube(s) based at least in part on a power consumption of the processor(s). In at least one embodiment, the system can include a controller to control the flow rate of the cooling fluid through the condenser tube(s) based at least in part on a temperature of the processor(s). The system can include one or more temperature sensors for sensing the temperature of the refrigerant and/or any, or each, of the processor(s). In at least one embodiment, the system can include a controller to control the flow rate of the cooling fluid through the condenser tube(s) based on a combination of any of a temperature of the refrigerant, a power consumption of the processor(s), and a temperature of the processor(s).

In at least one embodiment, a two-phase immersion cooling system can include a first pressure vessel, a second pressure vessel in selective fluid communication with the first pressure vessel, one or more processors within the second pressure vessel, a two-phase refrigerant within the first and second pressure vessels, and one or more condenser tubes within the first pressure vessel. In at least one embodiment, the refrigerant can be configured to extract heat from the processor(s). The refrigerant can flow past the processor(s) by thermosyphon. In at least one embodiment, a liquid phase of the refrigerant can fully, or at least partially, cover the processor(s). In at least one embodiment, the condenser tube(s) can be configured to receive cooling fluid into and transmit cooling fluid out of the first pressure vessel, thereby removing heat from the second pressure vessel. The cooling fluid, such as chilled water or a propylene glycol mixture can be supplied by an FCS, which may be external to, or integrated within, the system.

In at least one embodiment, the system can be modular. For example, in at least one embodiment, the system can include a third pressure vessel in selective fluid communication with the first pressure vessel, and one or more processors within the third pressure vessel, wherein the condenser tube(s) are further configured to remove heat from the third pressure vessel. In at least one embodiment, the third pressure vessel is identical to the second pressure vessel. In at least one embodiment, the third pressure vessel is functionally independent from the second pressure vessel, such that, for example, one can be cooled while the other is not, one can be cooled at a different rate than the other, one can be drained and opened while the other is being cooled, or any combination thereof.

In at least one embodiment, the system can include more than two processor housing pressure vessels. For example, the first pressure vessel can be referred to as a primary pressure vessel and the second pressure vessel can be referred to as a secondary pressure vessel. In at least one embodiment, the system can include multiple secondary pressure vessels, housing processors, in selective fluid communication with the first pressure vessel, with the condenser tube(s) configured to remove heat from any or all of the multiple secondary pressure vessels, which can include any number of secondary pressure vessels required or desired for an implementation of the disclosure. These secondary pressure vessels can all be identical to the second pressure vessel, as described herein, or there can be differences between or among two or more of the secondary pressure vessels and/or second pressure vessel. In at least one embodiment, the secondary pressure vessels are functionally independent from each other, such that, for example, one or more secondary pressure vessels can be cooled while one or more are not, one or more secondary pressure vessels can be cooled at a different rate than others, one or more secondary pressure vessels can be drained and opened while others are being cooled, or any combination thereof.

In at least one embodiment, the system can include one or more lines connected between the first pressure vessel and the second pressure vessel. In at least one embodiment, the system can include a first line and a second line connected between the first pressure vessel and the second pressure vessel. For example, in at least one embodiment, the system can include a liquid line connected between a lower portion of the first pressure vessel and a lower portion of the second pressure vessel and a vapor line connected between an upper portion of the first pressure vessel and an upper portion of the second pressure vessel. In at least one embodiment, the system can include one or more valves in either, or both, of the line(s) to selectively isolate the second pressure vessel from the first pressure vessel. For example, in at least one embodiment, the system can include one or more valves in the liquid line and one or more valves in the vapor line to selectively isolate the second pressure vessel from the first pressure vessel. In at least one embodiment, these valves can include, for example, quarter turn ball valves, or the like. In at least one embodiment, at least one of the valves is configured to control flow of the refrigerant between the second pressure vessel and the first pressure vessel. In at least one embodiment, at least one of the valves can be configured to supply and/or drain the refrigerant to/from the second pressure vessel and/or the first pressure vessel. In at least one embodiment, one or more valves can be or include, for example, a Schrader valve and/or one or more other types of valves suitable for implementing a physical embodiment of the disclosure.

In at least one embodiment, the second pressure vessel can be similar to the pressure vessel described above. For example, the second pressure vessel can be, or include, a chamber, which can include a flange and a plate bolted to the flange. The processor(s) can be mounted to, or otherwise physically secured to, the plate. In at least one embodiment, the processor(s) can receive power and communications through the plate, in much the same manner as described in connection with the pressure vessel 110 described above. In at least one embodiment, the second pressure vessel can include one or more valves configured to supply and/or drain the refrigerant to/from the second pressure vessel.

In at least one embodiment, the processor(s) can include a coating on an exterior surface thereof. Such a coating can minimize a temperature difference between the refrigerant and the processor(s) and/or the exterior surface thereof. Such a coating can electrically insulate the processor(s) from the refrigerant. In at least one embodiment, the processor(s) and/or the exterior surface thereof can be configured to electrically insulate the one or more processors from the refrigerant.

In at least one embodiment, the liquid phase of the refrigerant completely covers the processor(s). In at least one embodiment, one or more of the condenser tube(s) are positioned above the liquid phase of the refrigerant, in the first pressure vessel, such that the condenser tube(s) can condense a gaseous phase of the refrigerant. In at least one embodiment, all of the condenser tube(s) are positioned above the liquid phase of the refrigerant. In at least one embodiment, the refrigerant comprises a dielectric.

In at least one embodiment, the system can include a controller to control a flow rate of the cooling fluid through the condenser tube(s) based at least in part on a temperature of the refrigerant. In at least one embodiment, the system can include a controller to control the flow rate of the cooling fluid through the condenser tube(s) based at least in part on a power consumption of the processor(s). In at least one embodiment, the system can include a controller to control the flow rate of the cooling fluid through the condenser tube(s) based at least in part on a temperature of the processor(s). The system can include one or more temperature sensors for sensing the temperature of the refrigerant and/or any, or each, of the processor(s). In at least one embodiment, the system can include a controller to control the flow rate of the cooling fluid through the condenser tube(s) based on a combination of any of a temperature of the refrigerant, a power consumption of the processor(s), and a temperature of the processor(s).

In at least one embodiment, the system can include a controller to control a flow rate of the refrigerant based at least in part on a temperature of the refrigerant. In at least one embodiment, the system can include a controller to control the flow rate of the refrigerant based at least in part on a power consumption of the processor(s). In at least one embodiment, the system can include a controller to control the flow rate of the refrigerant based at least in part on a temperature of the processor(s). The system can include one or more temperature sensors for sensing the temperature of the refrigerant and/or any, or each, of the processor(s). In at least one embodiment, the system can include a controller to control the flow rate of the refrigerant based on a combination of any of a temperature of the refrigerant, a power consumption of the processor(s), and a temperature of the processor(s). Such a controller can control the flow rate of the refrigerant past the processor(s) and/or between the first pressure vessel and the second pressure vessel.

Other and further embodiments utilizing one or more aspects of the disclosure can be devised without departing from the spirit of Applicants' disclosure. For example, the devices, systems and methods can be implemented for numerous different types and sizes in numerous different industries. Further, the various methods and embodiments of the devices, systems and methods can be included in combination with each other to produce variations of the disclosed methods and embodiments. Discussion of singular elements can include plural elements and vice versa. The order of steps can occur in a variety of sequences unless otherwise specifically limited. The various steps described herein can be combined with other steps, interlineated with the stated steps, and/or split into multiple steps. Similarly, elements have been described functionally and can be embodied as separate components or can be combined into components having multiple functions.

The inventions have been described in the context of preferred and other embodiments and not every embodiment of the inventions has been described. Obvious modifications and alterations to the described embodiments are available to those of ordinary skill in the art having the benefits of the present disclosure. The disclosed and undisclosed embodiments are not intended to limit or restrict the scope or applicability of the inventions conceived of by the Applicants, but rather, in conformity with the patent laws, Applicants intend to fully protect all such modifications and improvements that come within the scope or range of equivalents of the following claims.

What is claimed is:

1. A two-phase immersion cooling system comprising:
a pressure vessel;
one or more processors within the vessel;
a two-phase refrigerant within the vessel, the refrigerant being configured to extract heat from the one or more processors, wherein a liquid phase of the refrigerant at least partially covers the one or more processors; and
one or more condenser tubes within the vessel, wherein the one or more condenser tubes are configured to receive cooling fluid into and cooling fluid out of the vessel, thereby removing heat from the vessel.

2. The system of claim 1, wherein the vessel comprises a chamber having a flange and a plate bolted to the flange, wherein the one or more processors are physically secured to the plate, and wherein the one or more processors receive power and communications through the plate.

3. The system of claim 1, wherein the one or more processors include a coating on an exterior surface thereof, the coating configured to minimize a temperature difference between the exterior surface and the refrigerant and to electrically insulate the one or more processors from the refrigerant.

4. The system of claim 1, wherein the liquid phase of the refrigerant completely covers the one or more processors and wherein the one or more condenser tubes are positioned above the liquid phase of the refrigerant, such that the condenser tubes are configured to condense a gaseous phase of the refrigerant.

5. The system of claim 1, further comprising a controller configured to control a flow rate of the cooling fluid through the one or more condenser tubes based at least in part on a refrigerant temperature of the refrigerant.

6. The system of claim 5, wherein the controller is configured to further control the flow rate of the cooling fluid through the one or more condenser tubes based on a power consumption of the one or more processors.

7. The system of claim 5, wherein the controller is configured to further control the flow rate of the cooling fluid through the one or more condenser tubes based on a processor temperature of the one or more processors.

8. A two-phase immersion cooling system comprising:
a first pressure vessel;
a second pressure vessel in selective fluid communication with the first pressure vessel;
one or more processors within the second pressure vessel;
a two-phase refrigerant within the first and second pressure vessels, the refrigerant being configured to extract heat from the one or more processors, wherein a liquid phase of the refrigerant at least partially covers the one or more processors; and
one or more condenser tubes within the first pressure vessel, wherein the one or more condenser tubes are configured to receive cooling fluid into and transmit cooling fluid out of the first pressure vessel, thereby removing heat from the second pressure vessel.

9. The system of claim 8, further including a liquid line connected between a lower portion of the first pressure vessel and a lower portion of the second pressure vessel and a vapor line connected between an upper portion of the first pressure vessel and an upper portion of the second pressure vessel.

10. The system of claim 8, wherein the second pressure vessel comprises a chamber having a flange and a plate bolted to the flange, wherein the one or more processors are physically secured to the plate, and wherein the one or more processors receive power and communications through the plate.

11. The system of claim 8, wherein the one or more processors include a coating on an exterior surface thereof, the coating configured to minimize a temperature difference between the exterior surface and the refrigerant.

12. The system of claim 8, wherein an exterior surface of the one or more processors is configured to electrically insulate the one or more processors from the refrigerant.

13. The system of claim 8, wherein the liquid phase of the refrigerant completely covers the one or more processors and wherein the one or more condenser tubes are positioned above the liquid phase of the refrigerant, such that the condenser tubes are configured to condense a gaseous phase of the refrigerant.

14. The system of claim 8, further comprising a controller configured to control a flow rate of the cooling fluid through the one or more condenser tubes based at least in part on a refrigerant temperature of the refrigerant.

15. The system of claim 14, wherein the controller is configured to further control the flow rate of the cooling fluid through the one or more condenser tubes based on a power consumption of the one or more processors.

16. The system of claim 14, wherein the controller is configured to further control the flow rate of the cooling fluid through the one or more condenser tubes based on a processor temperature of the one or more processors.

17. The system of claim 8, further comprising a controller configured to control a flow rate of refrigerant based at least in part on a refrigerant temperature of the refrigerant.

18. The system of claim 17, wherein the controller is configured to further control the flow rate of the refrigerant based on a power consumption of the one or more processors.

19. The system of claim 17, wherein the controller is configured to further control the flow rate of the refrigerant based on a processor temperature of the one or more processors.

20. The system of claim 17, further including a third pressure vessel in selective fluid communication with the first pressure vessel, and one or more processors within the third pressure vessel, wherein the one or more condenser tubes are further configured to remove heat from the third pressure vessel.
